(19) United States
(12) Patent Application Publication
(10) Pub. No.: US 2026/0287627 A1
(43) Pub. Date: Sep. 24, 2026

(54) TESTING APPARATUS FOR DETECTING OBSTRUCTIONS IN MULTI-LAYER CELLULAR STRUCTURES AND ASSOCIATED SYSTEM AND METHOD

(71) Applicant: The Boeing Company, Arlington, VA (US)

(72) Inventor: Eric Hofbeck, Lynwood, WA (US)

(21) Appl. No.: 19/088,580

(22) Filed: Mar. 24, 2025

(51) Int. Cl. G01R 27/16; G06F 3/16; H04R 1/02; H04R 3/00; H04R 29/00

(52) U.S. Cl. CPC G01R 27/16; G06F 3/162; H04R 1/025; H04R 3/00; H04R 29/001

(57) ABSTRACT

Disclosed herein is a testing apparatus for detecting obstructions in a multi-layer cellular structure and associated system and method. The testing apparatus includes a tube having a first end, a second end, and an internal passage extending between them. A loudspeaker is mounted within the internal passage proximate the first end and is configured to direct sound waves through the internal passage. A cap is at the second end of the tube and defines an opening through which the sound waves exit. During a testing operation, the testing apparatus is configured to be positioned on a testing surface of a multi-layer cellular structure to allow sound waves to interact with the structure. The testing apparatus measures electrical impedance to detect obstructions, such as adhesive blockages, that may disrupt wave transmission.

### FIELD

This disclosure relates generally to multi-layer cellular structure testing systems and more particularly to a testing apparatus for detecting obstructions in multi-layer cellular structures.

### BACKGROUND

Multi-layer cellular structures are used in various aerospace and industrial applications, including acoustic linings in jet engine inlets. These structures often rely on internal cellular architectures to achieve functional objectives such as sound attenuation, structural reinforcement, or fluid flow control. The effectiveness of these structures depends on maintaining specific performance characteristics, such as acoustic impedance, airflow resistance, or mechanical integrity. However, obstructions in the structures may result from adhesives used during a bonding process, accumulated debris, or manufacturing defects, which can inadvertently block portions of the cellular structure, potentially compromising performance. Detecting these blockages is challenging because they are often hidden within the structure and not externally visible, requiring specialized inspection techniques.

Conventional methods for detecting obstructions in multi-layer cellular structures are often expensive, complex, or impractical for in-situ inspections. As a result, manufactures lack an efficient and cost-effective means of verifying whether a multi-layer cellular structure is free from obstructions and performing as intended.

### SUMMARY

The subject matter of the present application has been developed in response to the present state of the art, and in particular, in response to the shortcomings in the evaluation of multi-layer cellular structures that have not yet been fully solved by currently available techniques. Accordingly, the subject matter of the present application has been developed to provide a testing apparatus and associated system and method that overcome at least some of the above-mentioned shortcomings of prior art techniques.

The following is a non-exhaustive list of examples, which may or may not be claimed, of the subject matter, disclosed herein.

Disclosed herein is a testing apparatus for detecting obstructions in a multi-layer cellular structure. The testing apparatus includes a tube having a first end, a second end, and a tube length extending between the first end and the second end. The tube defines an internal passage with a first cross-sectional dimension. A loudspeaker is mounted in the internal passage proximate the first end of the tube. The loudspeaker has a sound-emitting portion facing toward the second end of the tube and a non-emitting portion facing away from the second end of the tube. A cap is fixed to the second end of the tube. The cap includes an opening with a second cross-sectional dimension and the second cross-sectional dimension of the opening is smaller than the first cross-sectional dimension of the internal passage. Audio signal connectors are operably connected to the loudspeaker and extend from the tube, the audio signal connectors are configured to transmit a input signal to the loudspeaker and transmit a speaker output signal from the loudspeaker. The preceding subject matter of this paragraph characterizes example 1 of the present disclosure.

The testing apparatus includes a gasket attached to the cap and configured to form a seal between the cap and a testing surface of the multi-layer cellular structure. The preceding subject matter of this paragraph characterizes example 2 of the present disclosure, wherein example 2 also includes the subject matter according to example 1, above.

The testing apparatus includes a current sensing circuit electrically connected to the audio signal connectors and configured to measure a current associated with the speaker output signal. The testing apparatus also includes a voltage sensing circuit connected to the audio signal connectors and configured to measure a voltage associated with the speaker output signal. The preceding subject matter of this paragraph characterizes example 3 of the present disclosure, wherein example 3 also includes the subject matter according to any of examples 1-2, above.

The second cross-sectional dimension of the opening in the cap is between, and inclusive of, twenty percent and forty percent of the first cross-sectional dimension of the internal passage of the tube. The preceding subject matter of this paragraph characterizes example 4 of the present disclosure, wherein example 4 also includes the subject matter according to any of examples 1-3, above.

The second cross-sectional dimension of the opening in the cap is between, and inclusive of, 0.5 inches and 0.8 inches. The preceding subject matter of this paragraph characterizes example 5 of the present disclosure, wherein example 5 also includes the subject matter according to example 4, above.

The opening of the cap has a circular cross-section. The preceding subject matter of this paragraph characterizes example 6 of the present disclosure, wherein example 6 also includes the subject matter according to any of examples 1-5, above.

The testing apparatus includes a rear cap closing the first end of the tube. The loudspeaker is positioned proximate the rear cap within the internal passage. The preceding subject matter of this paragraph characterizes example 7 of the present disclosure, wherein example 7 also includes the subject matter according to any of examples 1-6, above.

The testing apparatus includes an acoustic sealing ring positioned around the sound-emitting portion of the loudspeaker. The acoustic sealing ring seals the loudspeaker within the internal passage such that sound emitted from the sound-emitting portion is directed into a forward portion of the internal passage. The preceding subject matter of this paragraph characterizes example 8 of the present disclosure, wherein example 8 also includes the subject matter according to any of examples 1-7, above.

Further disclosed herein is a system for detecting obstructions within a multi-layer cellular structure. The system includes a multi-layer cellular structure having a testing surface that is acoustically permeable and a testing apparatus configured to be positioned on the testing surface of the multi-layer cellular structure. The testing apparatus including a tube having a first end, a second end, and a tube length extending between the first end and the second end. The tube defines an internal passage with a first cross-sectional dimension. A loudspeaker is mounted in the internal passage proximate the first end of the tube. The loudspeaker has a sound-emitting portion facing toward the second end of the tube and a non-emitting portion facing away from the second end of the tube. A cap is fixed to the second end of the tube. The cap includes an opening with a second cross-sectional dimension and the second cross-sectional dimension of the opening is smaller than the first cross-sectional dimension of the internal passage. Audio signal connectors are operably connected to the loudspeaker and extend from the tube, the audio signal connectors are configured to transmit a input signal to the loudspeaker and transmit a speaker output signal from the loudspeaker. The system also includes an external audio interface operably coupled to the testing apparatus and configured to generate the input signal and receive the speaker output signal. The preceding subject matter of this paragraph characterizes example 9 of the present disclosure.

During testing, the external audio interface generates the input signal and transmits it to the loudspeaker via the audio signal connectors. The testing apparatus is positioned on the multi-layer cellular structure, such that the second end of the tube contacts the testing surface of the multi-layer cellular structure. The multi-layer cellular structure receives sound waves from the sound-emitting portion of the loudspeaker through the opening in the cap. The loudspeaker generates the speaker output signal and transmits the speaker output signal to the external audio interface via the audio signal connectors for analysis. The preceding subject matter of this paragraph characterizes example 10 of the present disclosure, wherein example 10 also includes the subject matter according to example 9, above.

The system includes a current sensing circuit electrically connected to the audio signal connectors and configured to measure a current associated with the speaker output signal as it returns from the loudspeaker to the external audio interface. The system also includes a voltage sensing circuit electrically connected to the audio signal connectors and configured to measure a voltage associated with the speaker output signal as it returns from the loudspeaker to the external audio interface. The preceding subject matter of this paragraph characterizes example 11 of the present disclosure, wherein example 11 also includes the subject matter according to any of examples 9-10, above.

The system includes a processing unit communicatively coupled to the external audio interface. The processing unit is configured to receive voltage and current data corresponding to the speaker output signal and determine an electrical impedance of the loudspeaker based on the voltage and current data. The electrical impedance represents acoustic absorption characteristics of the multi-layer cellular structure. The preceding subject matter of this paragraph characterizes example 12 of the present disclosure, wherein example 12 also includes the subject matter according to any of examples 9-11, above.

The processing unit is configured to compare a determined electrical impedance to a predetermined reference range and classify the multi-layer cellular structure as acceptable when the determined electrical impedance is at or within the predetermined reference range and as unacceptable when the determined electrical impedance is outside the predetermined reference range. The preceding subject matter of this paragraph characterizes example 13 of the present disclosure, wherein example 13 also includes the subject matter according to example 12, above.

The system includes a condition indicator communicatively coupled to the processing unit. The condition indicator generates an alert when the multi-layer cellular structure is classified as unacceptable. The preceding subject matter of this paragraph characterizes example 14 of the present disclosure, wherein example 14 also includes the subject matter according to example 13, above.

The processing unit is configured to determine the electrical impedance of the loudspeaker in real-time as the loudspeaker emits sound waves. The preceding subject matter of this paragraph characterizes example 15 of the present disclosure, wherein example 15 also includes the subject matter according to example 12, above.

The second cross-sectional dimension of the opening in the cap is selected based on a characteristic dimension of the multi-layer cellular structure. The characteristic dimension includes at least one of a perforation in a face sheet of the multi-layer cellular structure, a perforation density in the face sheet of the multi-layer cellular structure, or a cell cross-sectional dimension of an internal layer within the multi-layer cellular structure. The preceding subject matter of this paragraph characterizes example 16 of the present disclosure, wherein example 16 also includes the subject matter according to any of examples 9-15, above.

Further disclosed herein is a method for detecting obstructions in a multi-layer cellular structure. The method includes positioning a testing apparatus at an initial testing location on a testing surface that is acoustically permeable of the multi-layer cellular structure. The testing apparatus includes a loudspeaker enclosed within a tube and is configured to emit sound waves toward the multi-layer cellular structure through an opening. The method also includes transmitting a input signal from an external audio interface to the loudspeaker via audio signal connectors. The method further includes emitting sound waves from the loudspeaker through the opening of the testing apparatus toward the multi-layer cellular structure. Additionally, the method includes receiving a speaker output signal from the loudspeaker via the audio signal connectors, the speaker output signal providing voltage and current data associated with the interaction of the emitted sound waves with the multi-layer cellular structure. The method further includes determining an electrical impedance of the loudspeaker based on the voltage and current data corresponding to the loudspeaker. The electrical impedance represents acoustic absorption characteristics of the multi-layer cellular structure at the initial testing location. The preceding subject matter of this paragraph characterizes example 17 of the present disclosure.

The method includes comparing a determined electrical impedance to a predetermined reference range and classifying the multi-layer cellular structure as acceptable when the determined electrical impedance is at or within the predetermined reference range and unacceptable when the determined electrical impedance is outside the predetermined reference range. The preceding subject matter of this paragraph characterizes example 18 of the present disclosure, wherein example 18 also includes the subject matter according to example 17, above.

The method includes repositioning the testing apparatus at a subsequent testing location on the testing surface of the multi-layer cellular structure. The subsequent testing location is spaced apart from the initial testing location. The method also includes determining a subsequent electrical impedance of the loudspeaker at the subsequent testing location based on voltage and current data corresponding to the loudspeaker at the subsequent testing location. The subsequent electrical impedance represents acoustic absorption characteristics of the multi-layer cellular structure at the subsequent testing location. The preceding subject matter of this paragraph characterizes example 19 of the present disclosure, wherein example 19 also includes the subject matter according to any of examples 17-18, above.

Determining the electrical impedance of the loudspeaker is determined in real-time as the loudspeaker emits sound waves at the initial testing location. The preceding subject matter of this paragraph characterizes example 20 of the present disclosure, wherein example 20 also includes the subject matter according to any of examples 17-19, above.

The described features, structures, advantages, and/or characteristics of the subject matter of the present disclosure may be combined in any suitable manner in one or more examples and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example or implementation. In other instances, additional features and advantages may be recognized in certain examples and/or implementations that may not be present in all examples or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings, which are not necessarily drawn to scale, depict only certain examples of the subject matter and are not therefore to be considered to be limiting of its scope, the subject matter will be described and explained with additional specificity and detail through the use of the drawings, in which:

FIG. 1 is a schematic perspective view of one example of a testing apparatus for detecting obstructions in a multi-layer cellular structure, depicting a first end of the testing apparatus, according to one or more examples of the present disclosure;

FIG. 2 is a schematic perspective view of the testing apparatus of FIG. 1, depicting a second end of the testing apparatus, according to one or more examples of the present disclosure;

FIG. 3 is a cross-sectional side view of one example of the testing apparatus, taken along plane within which lies a central axis of the testing apparatus, according to one or more examples of the present disclosure;

FIG. 4A is a schematic block diagram of a system for detecting obstructions in a multi-layer cellular structure, according to one or more examples of the present disclosure;

FIG. 4B is a perspective and partial block diagram of a system for detecting obstructions in a multi-layer cellular structure, according to one or more examples of the present disclosure;

FIG. 5 is a schematic perspective view of the testing apparatus of FIG. 1, positioned with the second end of the testing apparatus in contact with a testing surface of a multi-layer cellular structure, according to one or more examples of the present disclosure; and

FIG. 6 is a schematic flow diagram of a method for detecting obstructions in a multi-layer cellular structure, according to one or more examples of the present disclosure.

### DETAILED DESCRIPTION

Reference throughout this specification to “one example,” “an example,” or similar language means that a particular feature, structure, or characteristic described in connection with the example is included in at least one example of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the present disclosure, however, absent an express correlation to indicate otherwise, an implementation may be associated with one or more examples.

Disclosed herein is a testing apparatus and associated system and method for detecting obstructions in a multi-layer cellular structure. The multi-layer cellular structure is acoustically permeable may include a porous or perforated face sheet, one or more layers of an internal cellular structure (e.g., honeycomb core), and a solid backing layer that provides structural support. This layered configuration allows for controlled transmission of air, sound, or other media through the face sheet and into the cellular structure, where the material properties and geometry of the internal cellular core influence how energy propagates or dissipates. For example, in acoustic applications, sound waves enter through the face sheet and interact with the internal cells, where they are either absorbed, dampened, or redirected to reduce noise. In aerospace applications, internal cellular cores may provide lightweight strength and impact resistance, while in filtration or ventilation systems, they may regulate fluid flow and diffusion.

One example of a multi-layer cellular structure is an acoustic lining used in jet engine inlets, which is designed to attenuate noise emissions by controlling the propagation of sound waves. The acoustic performance of acoustic linings depends on maintaining a specific acoustic absorption characteristics, which can be compromised by adhesive blockages introduced during manufacturing.

The disclosed testing apparatus provides a low-cost, portable, and efficient solution for detecting obstructions in multi-layer cellular structures, including acoustic linings. Unlike conventional methods that rely on microphones and complex instrumentation, the testing apparatus eliminates the need for microphones, thereby avoiding challenges associated with calibration, positioning, and maintenance of sensitive sensors. The testing apparatus operates by measuring an electrical impedance of the loudspeaker while the loudspeaker is contacting the multi-layer cellular structure, which is influenced by the interaction between emitted sound waves and the multi-layer cellular structure. In particular, variations in the acoustic absorption characteristics of the structure, such as those caused by obstructions within the internal cellular core, impact the electrical impedance of the loudspeaker, to enable the indirect detection of obstructions. By analyzing impedance variations, the testing apparatus can detect blockages that disrupt the intended propagation of sound waves within the structure.

The simplified design enables in-situ inspections, making it possible to assess multi-layer cellular structures both prior to installation and after integration into a final assembly, such as a jet engine inlet. Accordingly, the testing apparatus may be used to detect obstructions during pre-installation quality control, pre-service verification, and in-service inspections.

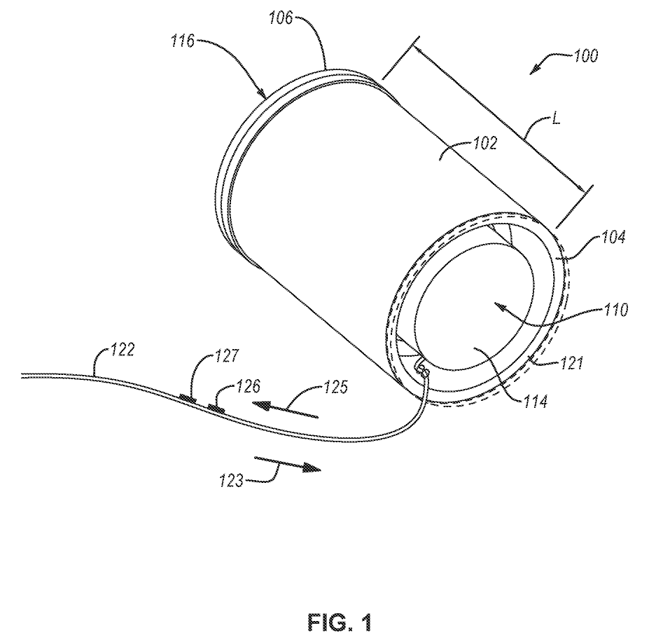

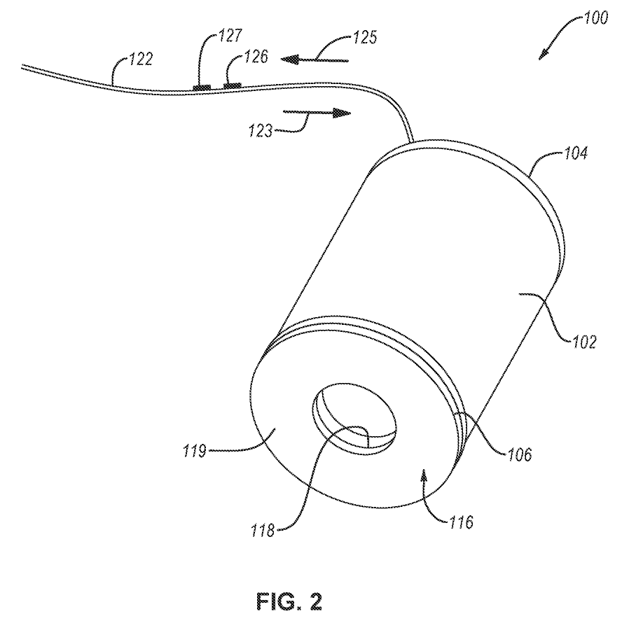

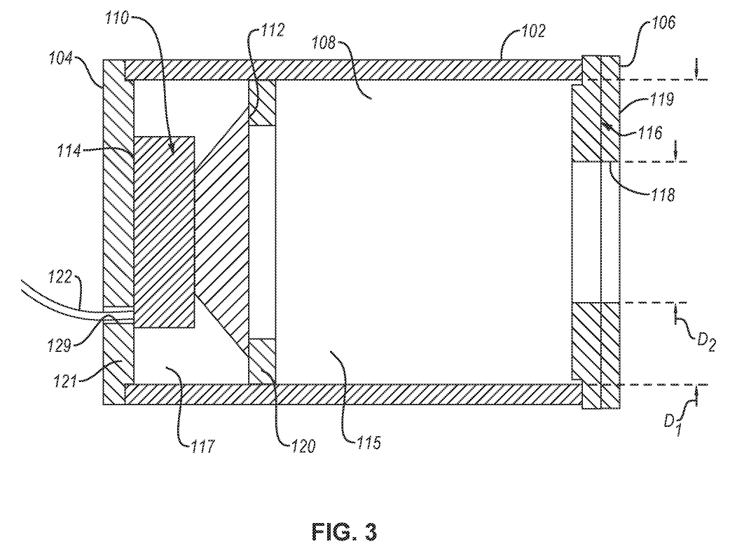

According to FIGS. 1 and 2, one example of a testing apparatus 100 is shown. The testing apparatus 100 includes a tube 102 having a first end 104, a second end 106, and a tube length (L) extending between the first end 104 and the second end 106. The tube 102 defines an internal passage 108 with a first cross-sectional dimension (D₁) (see, e.g., FIG. 3).

The tube 102 may be made of any of various materials suitable for obstruction-detection applications. In some examples, the tube 102 is made of a polymeric material, which provides a lightweight and cost-effective construction while maintaining sufficient structural strength. In other examples, the tube 102 is made from metallic materials, such as aluminum, to provide durability and resistance to deformation. In yet other examples, the tube is made of a composite material, which may include fiber-reinforced polymers or other engineered composites.

In some examples, the first cross-sectional dimension (D₁) corresponds to a diameter of a circular internal passage. However, the internal passage 108 may have alternative cross-sectional geometries depending on specific testing requirements. For example, in some implementations, the internal passage 108 of the tube 102 may have an elliptical or rectangular cross-section to accommodate different acoustic wave propagation characteristics or manufacturing constraints.

As shown in FIG. 1, the first end 104 of the tube 102 includes a loudspeaker 110 mounted in the internal passage 108 of the tube 102 to generate sound waves for evaluating the electrical impedance of the loudspeaker. The loudspeaker 110 has a sound-emitting portion 112 (see, e.g., FIG. 3), which is oriented (i.e., facing) toward the second end 106 of the tube 102, to direct sound waves through the internal passage 108 toward a testing surface during a testing operation. A non-emitting portion 114 of the loudspeaker 110 faces away from the second end 106. The loudspeaker 110 is capable of producing controlled and consistent sound waves over a desired frequency range suitable for acoustic absorption testing. As used herein, the loudspeaker 110 can be any of various types of speakers capable of generating sound waves for acoustic absorption testing. Additionally, the sound generated may be white noise or pink noise, which can be processed to break down into individual frequencies for analysis. White/pink noise allows for a comprehensive acoustic evaluation across a range of frequencies, to enable simultaneous assessment of multiple frequency responses in a single test.

The loudspeaker 110 is configured to direct sound waves through the internal passage 108 of the tube 102. Specifically, and referring to FIG. 3, the sound-emitting portion 112 of the loudspeaker 110 is positioned within the first end 104 of the tube 102 such that generated sound is transmitted down the tube without obstruction. The internal passage 108 includes a rearward portion 117, where the loudspeaker 110 is mounted and a forward portion 115, which extends unobstructed from the loudspeaker 110 toward the second end 106 and allows for the propagation of sound waves. In some examples, the entirety of the loudspeaker 110 is sized and shaped to fit securely within the first end 104 of the tube 102. Specifically, the loudspeaker 110 has a size smaller than the first cross-sectional dimension (D1) of the internal passage 108, to allow it to be positioned within the tube 102 without obstructing sound transmission. The loudspeaker 110 may be mounted in the internal passage 108 of the tube 102 in any suitable manner, including mechanical fasteners, adhesives, or press-fit engagement. The mounting configuration may be selected to ensure that the loudspeaker 110 remains securely in place during operation, even when subjected to vibrations or pressure variations during testing.

In some examples, the first end 104 of the tube 102 includes a rear cap 121, which is depicted in FIG. 1 with a dashed line to show the interior of the tube 102. As shown in FIG. 3, the rear cap 121 encloses the tube 102 at the first end 104 and thus defines a closed end of the tube 102. The rear cap 121 can serve as a mounting surface for the loudspeaker 110, securing it within the rearward portion 117 of the internal passage 108. In some examples, the rear cap 121 helps prevent sound waves produced by the sound-emitting portion 112 of the loudspeaker 110 from escaping through the first end 104 of the tube 102, thus ensuring that the sound waves are directed through the second end 106 of the tube 102.

As shown in FIG. 2, a cap 116 is provided at the second end 106 of the tube 102. The cap 116 functions to constrain and direct the sound waves generated by the loudspeaker 110, to ensure that the emitted sound waves are efficiently transmitted through the cap 116 toward the multi-layer cellular structure during testing. In some examples, the cap 116 is integrally formed with the second end 106 of the tube 102, such as through a molding or machining process. In other examples, the cap 116 is separately formed and secured to an open end at the second end 106 of the tube 102, such that the cap 116 remains in place during testing and is not intended to be removed or adjusted while sound waves are being emitted. The cap 116 may be secured to the tube 102 via mechanical fasteners, adhesives, or other attachment mechanisms.

The cap 116 defines an opening 118 having a second cross-sectional dimension (D₂), where the second cross-sectional dimension (D₂) is smaller than the first cross-sectional dimension (D₁) of the internal passage 108. The reduction in size focuses and directs the emitted sound waves toward the multi-layer cellular structure during testing. Specifically, the opening 118 increases the pressure of the emitted sound waves, prevents dispersion, and minimizes interference from reflections within the tube 102.

In some examples, the second cross-sectional dimension (D₂) corresponds to a diameter of a circular opening. However, the opening may have alternative cross-sectional geometries, depending on specific testing requirements. For examples, in some implementations, the opening 118 may have an elliptical or rectangular cross-section to influence acoustic wave propagation characteristics.

In some examples, the testing apparatus 100 includes a gasket 119 positioned at the second end 106 of the tube 102 and attached to the cap 116. The gasket 119 is configured to form a seal between the cap 116 and a testing surface during a testing operation. By forming a seal, the gasket 119 helps to prevent unintended sound leakage, to ensure that the emitted sound waves are directed through the opening 118 and into the multi-layer cellular structure. The seal may improve measurement accuracy by reducing external noise interference and reducing variations in sound pressure levels at the testing surface. The gasket 119 may be made of a compliant material, such as rubber or foam, to conform to surface irregularities. In some examples, the gasket 119 and the cap 116 are formed as a single, unitary structure, such that the gasket 119 provides a seal while maintaining an unobstructed pathway for sound waves through the opening 118.

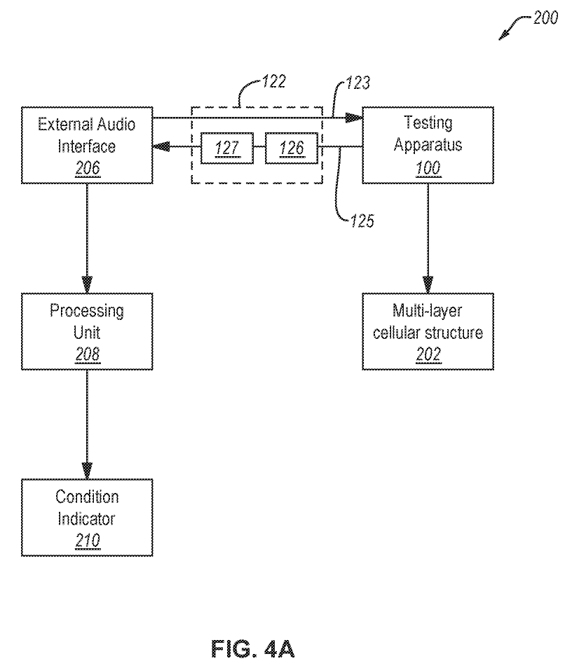

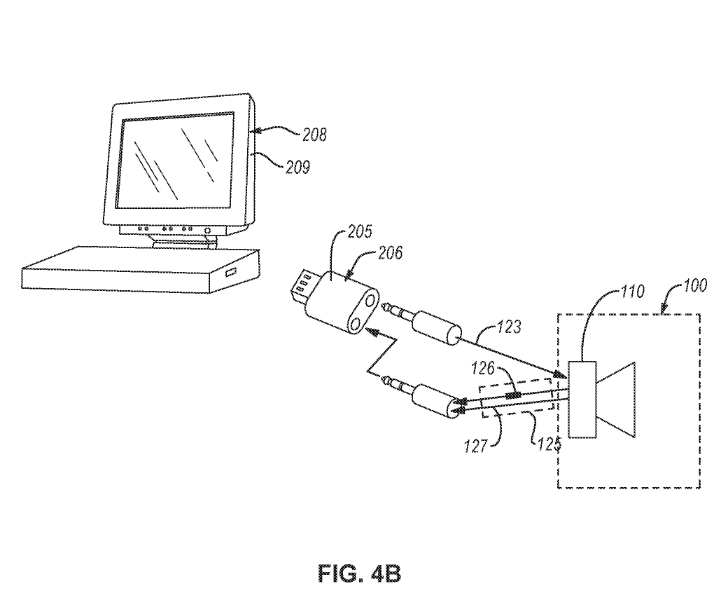

The testing apparatus 100 also includes audio signal connectors 122. The audio signal connectors 122 are operably connected to the loudspeaker 110 and extend from the tube 102. The audio signal connectors 122 facilitate bidirectional electrical communication between the loudspeaker 110 and an external audio interface (see, e.g., FIG. 4). During a testing operation, a input signal 123 is transmitted, via the audio signal connectors 122, from the external audio interface to the loudspeaker 110, to cause the loudspeaker 110 to generate sound waves. Additionally, a speaker output signal 125 (i.e., return signal) is transmitted, via the audio signal connectors 122, away from the loudspeaker 110 to the external audio interface for analysis.

The input signal 123 is a monaural electrical signal that drives the loudspeaker 110 to generate sound waves, which are propagated through the internal passage 108 of the tube 102 and exit through the opening 118 in the cap 116. The characteristics of the input signal 123, such as frequency and amplitude, may be adjusted to accommodate different test conditions. The speaker output signal 125 is an electrical signal transmitted from the loudspeaker 110 back to the external audio interface via the audio signal connectors 122. The speaker output signal 125 contains electrical characteristics (i.e., voltage and current) that reflect the interaction between the emitted sound waves and the multi-layer cellular structure.

In some examples, the audio signal connectors 122 may be shielded cables to minimize electromagnetic interference and preserve signal integrity. The audio signal connectors 122 may include standard audio jacks, terminal blocks, or custom connectors, depending on the configuration. Additionally, the audio signal connectors 122 may include conductive shielding or differential signal pathways to improve noise rejection and ensure accurate acoustic measurements.

In some examples, as shown in FIG. 4, the testing apparatus 100 includes a current sensing circuit 126 configured to measure current flowing through the loudspeaker 110 and a voltage sensing circuit 127 configured to measure a voltage associated with the loudspeaker 110. That is, the current sensing circuit 126 and the voltage sensing circuit 127 collect electrical data that may be used for determining the electrical impedance of the loudspeaker 110, which represents acoustic absorption characteristics of the multi-layer cellular structure. The current sensing circuit 126 and the voltage sensing circuit 127 may be positioned along the speaker output signal 125 of the audio signal connectors 122, where they monitor the electrical signals transmitted from the loudspeaker 110 back to the external audio interface. Specifically, one channel of the speaker output signal 125 measures a voltage applied to the loudspeaker 110 via the voltage sensing circuit 127, while another channel of the speaker output signal 125 measures a voltage drop, via the current sensing circuit 126, from the loudspeaker 110.

In some examples, the current sensing circuit 126 is a shunt resistor of sufficiently low resistance (e.g., milliohm range) in series with the loudspeaker 110, such that the voltage drop across the shunt resistor provides a means of calculating a current flowing from the loudspeaker 110. The voltage sensing circuit 127, on the other hand, may be configured to measure the voltage directly applied across the loudspeaker 110, allowing for simultaneous collection of voltage and current data. That is, the voltage sensing circuit 127 may corresponding to a wire within the audio signal connector 122, enabling monitoring of the applied voltage without requiring additional external circuitry.

In other examples, the current sensing circuit 126 and the voltage sensing circuit 127 may be positioned at a different location, separate from, but in electrical communication with, the testing apparatus 100. For example, the current sensing circuit 126 may be located inside the external audio interface or positioned along a dedicated measurement path separate from the audio signal connectors 122. Regardless of placement, the current sensing circuit 126 and the voltage sensing circuit 127 may provide measurement data, which, when analyzed together, enable the calculation of the electrical impedance of the loudspeaker 110.

Referring to FIG. 3, a cross-sectional view of one example of the testing apparatus 100, showing the internal configuration of the testing apparatus 100, is shown. The tube 102 extends along a longitudinal axis from the first end 104 to the second end 106, defining the internal passage 108 having the first cross-sectional dimension (D1). The internal passage 108 serves as a waveguide, directing sound waves generated by the loudspeaker 110 toward the opening 118 in the cap 116.

As shown, the testing apparatus 100 includes the rear cap 121. To accommodate the audio signal connectors 122 leading to the loudspeaker 110, the rear cap includes a wire exit 129 that allows the audio signal connectors 122 to pass through. The wire exit 129 is configured to allow for proper routing of the audio signal connectors 122. In some examples, the wire exit 129 is sealed using a grommet, adhesive sealant, tight-fit hole, or other sealing mechanism.

To further improve sound directionality, in some examples, an acoustic sealing ring 120 is positioned around the sound-emitting portion 112 of the loudspeaker 110. The acoustic sealing ring 120 effectively divides the internal passage 108 into the forward portion 115 and the rearward portion 117. Specifically, the acoustic sealing ring 120 forms a seal around a perimeter of the loudspeaker 110 while defining a central opening that allows sound waves to pass from the sound-emitting portion 112 into the forward portion 115 of the internal passage 108. By constraining and directing the emitted sound waves into the forward portion 115 of the internal passage 108, the acoustic sealing ring 120 reduces the risk of sound leakage toward the first end 104 of the tube 102 and improves the efficiency of sound transmission toward the multi-layer cellular structure.

In some examples, the acoustic sealing ring 120 is made from compliant materials that effectively form a tight seal around the loudspeaker 110 while absorbing excess vibrations. Suitable materials include, but are not limited to, foam, rubber, and elastomeric polymers. For example, the acoustic sealing ring 120 may be made from a closed-cell foam material, which may offer improved sound isolation by preventing unwanted air leaks and minimizing acoustic reflections to the rearward portion 117 of the internal passage 108. Additionally, materials with damping properties may be used to reduce resonance effects, to improve accuracy in acoustic responses.

The second cross-sectional dimension (D₂) of the cap 116 is smaller than the first cross-sectional dimension (D₁) of the internal passage 108. In some examples, the second cross-sectional dimension (D₂) of the opening 118 is between twenty percent and forty percent of the first cross-sectional dimension (D₁) of the internal passage 108 of the tube 102. For example, in certain implementations, the first cross-sectional dimension (D₁) of the internal passage 108 is between, and inclusive of, 2 inches and 2.5 inches, while the second cross-sectional dimension (D₂) of the opening 118 is between, and inclusive of, 0.5 inches and 0.8 inches. The reduction in size from (D₁) to (D₂) helps concentrate and direct the emitted sound waves, to ensure that the sound waves interact effectively with the acoustic lining, which is important for accurately measuring the electrical impedance of the multi-layer cellular structure, as it reduces wave dispersion and improves test repeatability.

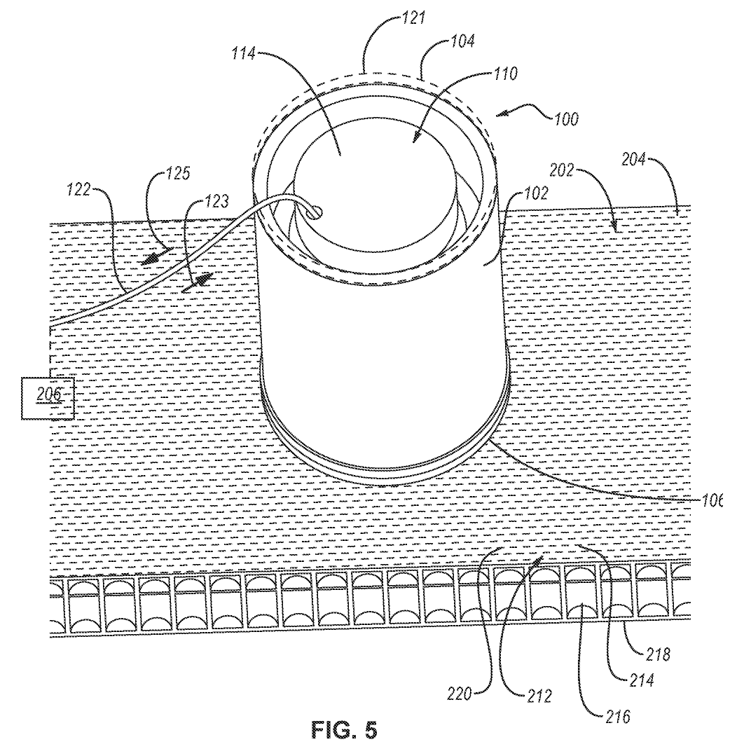

As shown in FIGS. 4A, 4B, and 5, one example of a system 200 for detecting obstructions in a multi-layer cellular structure 202 is disclosed. Specifically referring to FIG. 5, the system 200 includes a multi-layer cellular structure 202 having a testing surface 204 that is acoustically permeable. As used herein, acoustically permeable refers to a surface that allows at least a portion of incident sound waves to pass through rather than reflecting them entirely. This may be achieved through perforations, porosity, or other structural features that facilitate sound wave transmission into underlying layers of the multi-layer cellular structure 202. In some examples, the multi-layered cellular structure 202 includes a face sheet 214, at least one internal cellular layer 216, and a backing layer 218.

The face sheet 214 serves as the outermost layer of the multi-layer cellular structure 202 and is configured to enable sound wave transmission into the internal cellular layers 216. The face sheet 214 is acoustically permeable, such that it includes perforations, pores, or other structural features that facilitate the passage of sound waves into the underlying layers of the multi-layer cellular structure 202. In some examples, the face sheet 214 includes a plurality of perforations 220 that facilitate wave transmission through the face sheet 214. The perforations 220 may be circular, elongated, or irregularly shaped openings that are distributed across the face sheet 214 in a uniform or non-uniform pattern. The size, shape, and spacing of the perforations 220 may be selected based on the desired acoustic absorption characteristics of the multi-layer cellular structure 202.

The internal cellular layer 216 is structurally designed to influence wave propagation, energy dissipation, or load distribution, depending on the intended function of the multi-layer cellular structure. This layer may include a honeycomb core, lattice framework, or other cellular configurations that serve to dissipate acoustic energy and reduce overall noise levels. A honeycomb structure, for instance, functions as a sound-absorbing medium by trapping and gradually attenuating sound waves that pass through the face sheet 214. Additionally, in some examples, the internal cellular layer 216 may enhance mechanical strength, thermal insulation, or controlled fluid flow, depending on the specific design and application. The backing layer 218 provides structural reinforcement and, in some cases, acts as a reflective barrier that influences wave behavior within the structure. The combination of these layers creates a functional multi-layer cellular structure that can be tailored for different performance needs, including acoustic attenuation, structural support, or airflow regulation.

In some examples, the multi-layer cellular structure 202 is an acoustic lining 212 used in jet engine inlets. The acoustic lining 212 is configured to attenuate noise emissions by controlling the propagation of sound waves within the jet engine inlet environment. The acoustic lining 212 includes a face sheet 214, generally with a plurality of perforations 220, at least one internal cellular layer 216, and a backing layer 218. The layers of the acoustic lining 212 are bonded together using an adhesive. However, during the bonding process, excess adhesive may flow into the internal cellular layers, partially or fully blocking the cellular structure. Any obstruction can alter the acoustic absorption characteristics of the acoustic lining 212, reducing the effectiveness in adsorbing and dissipating sound waves. Blockages may be non-uniform, affecting specific areas of the acoustic lining 212 while leaving other portions functional.

In some examples, the size of the second cross-sectional dimension (D₂) of the opening 118 in the cap 116 is selected based on a characteristic dimension of the multi-layer cellular structure 202. The characteristic dimension may include at least one of a size of a perforation 220 in the face sheet 214, a perforation density (e.g., number of perforations per unit area), or a cell size of a cell within the internal cellular layer 216. In some examples, the opening 118 is configured to cover multiple perforations 220 in the face sheet 214 at once during a testing operation. This allows the system 200 to evaluate the electrical impedance of the loudspeaker 110 as influenced by the acoustic absorption characteristics of a representative section of the multi-layer cellular structure 202, rather than a single perforation. By tailoring the second cross-sectional dimension (D₂) to be sized relative to the structural characteristics of the multi-layer cellular structure 202, the system 200 optimizes the transmission and measurement of sound waves, improving the accuracy of impedance calculations.

The testing apparatus 100 may be utilized as a post-bonding inspection tool for evaluating the electrical impedance of the loudspeaker 110 and detecting regions where adhesive blockage, or other obstructions, have compromised acoustic performance of the multi-layer cellular structure 202. Specifically, during testing, the testing apparatus 100 is positioned on the testing surface 204 (i.e., the face sheet 214) of the multi-layer cellular structure 202, such that the second end 106 of the tube 102 contacts the testing surface 204 of the multi-layer cellular structure 202.

The testing apparatus 100 can be used for quality control to verify that the multi-layer cellular structure 202 meets design specifications and is free from defects, such as adhesive blockages, before installation. In some examples, the testing apparatus 100 may also be used in maintenance applications to assess the condition of the multi-layer cellular structure 202 over time. That is, the testing apparatus 100 may be deployed during routine inspections of an aircraft to detect degradation, contamination, or structural changes that impact the acoustic performance of the multi-layer cellular structure 202. By periodically evaluating the acoustic absorption characteristics of the multi-layer cellular structure 202, maintenance personnel can identify areas requiring repair or replacement, ensuring continued noise-reducing effectiveness throughout the structure’s operational lifespan.

Referring to FIGS. 4A, 4B, and 5, the system 200 includes an external audio interface 206 configured to generate and receive electrical signals used in evaluating the multi-layer cellular structure 202. The external audio interface 206 is operably connected to the testing apparatus 100 via the audio signal connectors 122, to facilitate bidirectional communication.

In operation, the external audio interface 206 generates an input signal 123 and transmits it to the loudspeaker 110 through the audio signal connectors 122. The loudspeaker 110 converts the electrical signal into sound waves, which propagate through the internal passage 108 of the tube 102 and exit through the opening 118 in the cap 116 toward the testing surface 204 of the multi-layer cellular structure 202. The external audio interface 206 receives a speaker output signal 125 from the loudspeaker 110 via the audio signal connectors 122, where the signal reflects the interaction between the emitted sound waves and the multi-layer cellular structure 202. The speaker output signal 125 contains multiple channels of electrical measurement data. In some examples, one channel of the speaker output signal 125 corresponds to the voltage applied to the loudspeaker 110, while another channel corresponds to a voltage drop measured across a current sensing circuit 126, which is indicative of the current flowing through the loudspeaker 110. By capturing both voltage and current data, the external audio interface 206 enables electrical impedance calculations to assess the acoustic absorption characteristics of the multi-layer cellular structure 202.

The external audio interface 206 may include various signal generation devices, for example, a portable computer sound card, a sound card adapter, a digital audio processor, a portable acoustic analyzer, or other signal processing hardware capable of generating and analyzing acoustic test signals. As shown in FIG. 4B, in some examples, the external audio interface 206, is a sound card 205, such as a USB sound card, configured to be inserted into a corresponding receiver in a computer. The sound card 205 is responsible for transmitting the input signal 123 to the loudspeaker 110 and receiving the speaker output signal 125 from the loudspeaker 110, which carries electrical measurement data (i.e. voltage and current data). The external audio interface 206 may be connected to the loudspeaker 110 via standard 1/8^{th} inch (i.e., 3.5 mm) audio plugs, to enable compatibility with commercially available sound cards and measurement systems. The current sensing circuit 126 is placed in series with the loudspeaker 110 along the speaker output signal 125 to measure the current flowing through the loudspeaker 110. The voltage sensing circuit 127, which may consist of direct electrical connections (e.g., wire or probe configuration), measures the voltage across the loudspeaker 110.

Referring to FIG. 4A and 4B, the system 200 also includes a processing unit 208 configured to receive voltage and current data corresponding to the speaker output signal 125 and determine an electrical impedance of the loudspeaker 110 based on the voltage and current data. In some examples, the processing unit 208 is integrated within the external audio interface 206, such as in a computer or digital signal processor that receives and processes the signal data. In other examples, the processing unit 208 is a standalone computing device, separate from the external audio interface 206, and communicatively coupled via a wired or wireless connection. As shown in FIG. 4B, a computer 209 may function as the processing unit 208, with the external audio interface 206 (i.e. sound card 205) communicatively couplable to the computer 209. The processing unit 208 executes algorithms to analyze the received data and assess the acoustic absorption characteristics of the multi-layer cellular structure 202.

In some examples, the processing unit 208 calculates electrical impedance of the loudspeaker 110 by dividing the measured voltage by the measured current. The resulting electrical impedance value represents the acoustic absorption characteristics of the multi-layer cellular structure 202, providing an indication of whether the testing apparatus 100 is positioned over an acoustically permeable section of the multi-layer cellular structure 202 or over a section that may be obstructed due to adhesive contamination introduced during manufacturing. Additionally, or alternatively, the electrical impedance may indicate whether blockage or degradation has occurred over time due to operational wear, environmental exposure, or accumulated debris during use.

The processing unit 208 is further configured to compare the determined electrical impedance of the loudspeaker 110 to a predetermined reference range. The reference range may be established based on known performance criteria, empirical testing data, or manufacturer specifications for the multi-layer cellular structure 202. By comparing the measured electrical impedance to the predetermined reference range, the processing unit 208 classifies the multi-layer cellular structure 202 using a go/no-go evaluation. Specifically, when the electrical impedance is at or within the predetermined range, indicating proper functionality, the multi-layer cellular structure 202 receives a ‘go’ (i.e., acceptable) classification. Conversely, if the electrical impedance is outside the predetermined reference range, the processing unit 208 assigns a ‘no-go’ (i.e. unacceptable) classification, indicating potential defects such as blocked perforations, excess adhesive buildup, or other structural inconsistencies that may impact acoustic performance. The classification results may be stored for further analysis or transmitted to a user interface for immediate evaluation.

In some examples, the processing unit 208 is configured to determine the electrical impedance of the loudspeaker 110 in real-time or near real-time, accounting for minor processing delays, as the loudspeaker emits sound waves. This rapid analysis enables immediate assessment of the multi-layer cellular structure 202 without requiring post-processing delays, to facilitate efficient quality control during manufacturing or maintenance inspections. By continuously monitoring impedance characteristics, the system 200 can identify inconsistencies or deviations as they occur, improving efficiency and reducing the likelihood of undetected acoustic blockages.

In some examples, the system 200 includes a condition indicator 210 in electrical communication with the processing unit 208. The condition indicator 210 is configured to generate an alert when the multi-layer cellular structure 202 is classified as unacceptable based on the determined electrical impedance. The alert may be provided in various forms, such as a visual indicator (e.g., an LED display or a screen notification), an audible alarm, or a data log entry within the processing unit 208. In some examples, the condition indicator 210 provides a real-time status update during testing, allowing an operator to take immediate corrective action if the multi-layer cellular structure 202 exhibits an electrical impedance outside the predetermined reference range. Accordingly, the condition indicator 210 provides direct feedback on the acoustic absorption characteristics of the tested multi-layer cellular structure 202.

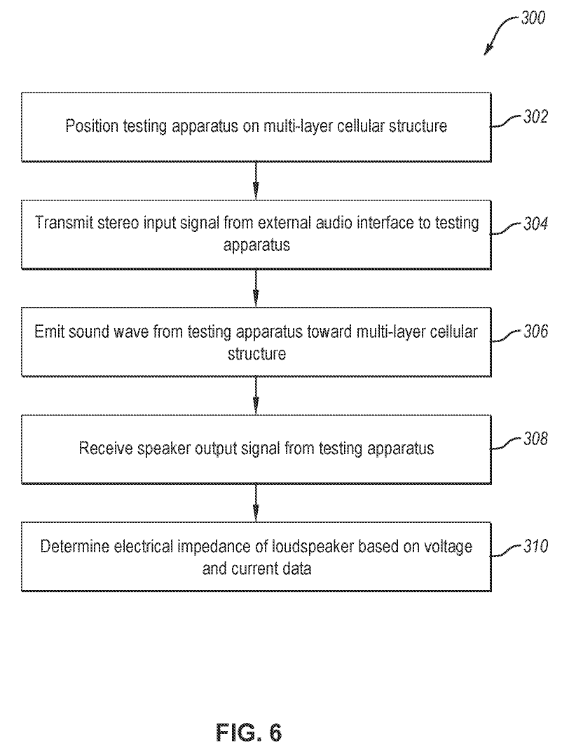

Referring to FIG. 6 is a method 300 for detecting obstructions in a multi-layer cellular structure 202. The method 300 includes (block 302) positioning a testing apparatus 100 at an initial testing location that is acoustically permeable on a testing surface 204 of the multi-layer cellular structure 202. The testing apparatus 100 includes a loudspeaker 110 enclosed within a structure (e.g., tube) and configured to emit sound waves toward the multi-layer cellular structure 202 through an opening 118. That is, the testing apparatus 100 is configured to generate and direct sound waves toward the multi-layer cellular structure 202 to assess its acoustic absorption characteristics. Proper positioning helps ensure that the structure forms a seal with the testing surface 204, minimizing unintended sound leakage and improving measurement accuracy. The initial testing location may correspond to a specific region of interest on the multi-layer cellular structure 202, where variations in impedance may indicate potential defects or blockages.

The method 300 further includes (block 304) transmitting a input signal 123 from an external audio interface 206 to the loudspeaker 110 via audio signal connectors 122. The input signal 123 serves as an excitation signal, driving the loudspeaker 110 to produce controlled acoustic waves with specific frequency and amplitude characteristics. The parameters of the input signal 123 may be adjusted to simulate different acoustic test conditions. In response to receiving the input signal 123, the loudspeaker 110 emits (block 306) sound waves through the opening 118 of the structure toward the multi-layer cellular structure 202. The shape and dimensions of the opening 118 may help direct the emitted sound waves toward the testing surface 204 of the multi-layer cellular structure 202 in a focused manner. The emitted sound waves interact with the multi-layer cellular structure 202, where the face sheet 214 allows the sound waves to enter the internal cellular structure for attenuation. In some examples, the frequency of the emitted sound waves is varied over time to analyze the frequency-dependent acoustic properties of the multi-layer cellular structure 202.

The method 300 further includes (block 308) receiving a speaker output signal 125 from the loudspeaker 110 via the audio signal connectors 122, the speaker output signal 125 representing electrical characteristics (i.e., voltage and current data) associated with the interaction of the emitted sound waves with the multi-layer cellular structure 202 at the initial testing location. The speaker output signal 125 is influenced by changes in voltage and current that correspond to the acoustic absorption characteristics of the multi-layer cellular structure 202, which may be indicative of blockages, inconsistencies, or variations in the structure’s construction. Based on the received voltage and current data, the method 300 includes (block 310) determining an electrical impedance of the loudspeaker 110. The electrical impedance represents acoustic absorption characteristics of the multi-layer cellular structure at the initial testing location. In some examples, the method 300 includes dynamically adjusting the test signal parameters, such as frequency or amplitude, to obtain a more comprehensive electrical impedance characterization across a range of conditions. The determined electrical impedance may be used to classify the multi-layer cellular structure 202 as acceptable or unacceptable based on deviation from the expected electrical impedance range.

Electrical impedance measurement is effective for obstruction detection because variations in electrical impedance indicate changes in how sound waves propagate through the testing location of the multi-layer cellular structure. An unobstructed structure exhibits a predictable electrical impedance response, while blockages, such as adhesive obstructions, alter the electrical impedance by disrupting the transmission and absorption of sound waves. By analyzing these electrical impedance deviations, the testing apparatus 100 can identify and locate potential obstructions that may compromise structural performance.

After determining the electrical impedance for the loudspeaker, which represents the initial testing location of the multi-layer cellular structure 202, the method 300 further includes comparing the determined electrical impedance to a predetermined reference range. The reference range may be established based on known acceptable performance characteristics of the multi-layer cellular structure 202. In some examples, the reference range is obtained by measuring the electrical impedance of the loudspeaker 110 corresponding to a multi-layer cellular structure that is free of known obstructions, such as a structure manufactured under ideal conditions with verified perforation integrity and no adhesive contamination. Alternatively, the reference range may be determined through empirical testing of multiple samples with varying levels of known obstructions, allowing for the development of a threshold range that distinguishes acceptable from unacceptable conditions. By comparing the measured electrical impedance with the reference values, the method 300 classifies the multi-layer cellular structure 202 as acceptable if the determined electrical impedance is at or within the reference range. Conversely, if the determined electrical impedance falls outside the predetermined reference range, the multi-layer cellular structure 202 is classified as unacceptable, indicating potential defects such as blocked perforations, excessive adhesive buildup, or other structural irregularities. This classification enables quality control assessments and supports corrective actions when necessary.

To ensure a comprehensive evaluation of the multi-layer cellular structure 202, the method 300 further includes repositioning the testing apparatus 100 at a subsequent testing location on the testing surface 204. The subsequent testing location is spaced apart from the initial testing location. A subsequent electrical impedance of the loudspeaker 110 is determined at the subsequent testing location based on voltage and current data corresponding to the loudspeaker 110 at the subsequent testing location. Although referred to as a subsequent testing location, multiple such locations can be testing to obtain a more comprehensive assessment of the multi-layer cellular structure 202. That is, each subsequent testing location allows for an additional measurement point across the multi-layer cellular structure 202, to enable a broader evaluation of the acoustic absorption characteristics of the multi-layer cellular structure 202. By repeating the electrical impedance determination at different locations, the method 300 enables detection of localized anomalies, non-uniform adhesive distribution, or variations in perforation quality. This step provides a more complete assessment of the acoustic absorption characteristics of the multi-layer cellular structure 202 and enables the mapping of electrical impedance variations across the surface.

In some examples, the method 300 includes determining the electrical impedance of the loudspeaker 110 in real-time, or near real-time. Real-time electrical impedance determination allows for efficient monitoring and instantaneous feedback on the condition of the multi-layer cellular structure 202. By analyzing the speaker output signal 125 as it is received, the system 200 can dynamically assess electrical impedance variations without requiring post-processing delays. This capability is beneficial for efficient manufacturing inspections and on-site maintenance assessments, helping enable immediate identification of any acoustic discrepancies in the multi-layer cellular structure.

In the above description, certain terms may be used such as "up," "down," "upper," "lower," "horizontal," "vertical," "left," "right," “over,” “under” and the like. These terms are used, where applicable, to provide some clarity of description when dealing with relative relationships. But, these terms are not intended to imply absolute relationships, positions, and/or orientations. For example, with respect to an object, an "upper" surface can become a "lower" surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.” Moreover, unless otherwise noted, as defined herein a plurality of particular features does not necessarily mean every particular feature of an entire set or class of the particular features.

The term “about” or “substantially” in some embodiments, is defined to mean within +/-5% of a given value, however in additional embodiments any disclosure of “about” may be further narrowed and claimed to mean within +/- 4% of a given value, within +/- 3% of a given value, within +/- 2% of a given value, within +/- 1% of a given value, or the exact given value. Further, when at least two values of a variable are disclosed, such disclosure is specifically intended to include the range between the two values regardless of whether they are disclosed with respect to separate embodiments or examples, and specifically intended to include the range of at least the smaller of the two values and/or no more than the larger of the two values. Additionally, when at least three values of a variable are disclosed, such disclosure is specifically intended to include the range between any two of the values regardless of whether they are disclosed with respect to separate embodiments or examples, and specifically intended to include the range of at least the A value and/or no more than the B value, where A may be any of the disclosed values other than the largest disclosed value, and B may be any of the disclosed values other than the smallest disclosed value.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms "first," "second," etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present subject matter may be embodied in other specific forms without departing from its spirit or essential characteristics. The described examples are to be considered in all respects only as illustrative and not restrictive. All changes which come within the meaning and range of equivalency of the claims are to be embraced within their scope.

What is claimed is:

1. A testing apparatus for detecting obstructions in a multi-layer cellular structure, the testing apparatus comprising:
a tube comprising a first end, a second end, and a tube length (L) extending between the first end and the second end, wherein the tube defines an internal passage with a first cross-sectional dimension;
a loudspeaker mounted in the internal passage proximate the first end of the tube, wherein the loudspeaker has a sound-emitting portion facing toward the second end of the tube and a non-emitting portion facing away from the second end of the tube;
a cap at the second end of the tube, wherein the cap comprises an opening with a second cross-sectional dimension and the second cross-sectional dimension of the opening is smaller than the first cross-sectional dimension of the internal passage; and
audio signal connectors operably connected to the loudspeaker and extending from the tube, the audio signal connectors configured to transmit a input signal to the loudspeaker and transmit a speaker output signal from the loudspeaker.

2. The testing apparatus of claim 1, further comprising a gasket attached to the cap and configured to form a seal between the cap and a testing surface of the multi-layer cellular structure.

3. The testing apparatus of claim 1, further comprising:
a current sensing circuit electrically connected to the audio signal connectors and configured to measure a current associated with the speaker output signal; and
a voltage sensing circuit electrically connected to the audio signal connectors and configured to measure a voltage associated with the speaker output signal.

4. The testing apparatus of claim 1, wherein the second cross-sectional dimension of the opening in the cap is between, and inclusive of, twenty percent and forty percent of the first cross-sectional dimension of the internal passage of the tube.

5. The testing apparatus of claim 4, wherein the second cross-sectional dimension of the opening in the cap is between, and inclusive of, 0.5 inches and 0.8 inches.

6. The testing apparatus of claim 1, wherein the opening of the cap has a circular cross-section.

7. The testing apparatus of claim 1, further comprising a rear cap closing the first end of the tube, wherein the loudspeaker is positioned proximate the rear cap within the internal passage.

8. The testing apparatus of claim 1, further comprising an acoustic sealing ring positioned around the sound-emitting portion of the loudspeaker, wherein the acoustic sealing ring seals the loudspeaker within the internal passage such that sound emitted from the sound-emitting portion is directed into a forward portion of the internal passage.

9. A system for detecting obstructions in a multi-layer cellular structure, the system comprising:
a multi-layer cellular structure comprising a testing surface that is acoustically permeable;
a testing apparatus configured to be positioned on the testing surface of the multi-layer cellular structure, the testing apparatus comprising:
a tube comprising a first end, a second end, and a tube length extending between the first end and the second end, wherein the tube defines an internal passage with a first cross-sectional dimension;
a loudspeaker mounted in the internal passage proximate the first end of the tube, wherein the loudspeaker has a sound-emitting portion facing toward the second end of the tube and a non-emitting portion facing away from the second end of the tube;
a cap at to the second end of the tube, wherein the cap comprises an opening with a second cross-sectional dimension and the second cross-sectional dimension of the opening is smaller than the first cross-sectional dimension of the internal passage; and
audio signal connectors operably connected to the loudspeaker and extending from the tube, the audio signal connectors configured to transmit a input signal to the loudspeaker and transmit a speaker output signal from the loudspeaker; and
an external audio interface operably coupled to the testing apparatus and configured to generate the input signal and receive the speaker output signal.

10. The system of claim 9, wherein, during testing:
the external audio interface generates the input signal and transmits to the loudspeaker via the audio signal connectors;
the testing apparatus is positioned on the multi-layer cellular structure, such that the second end of the tube contacts the testing surface of the multi-layer cellular structure;
the multi-layer cellular structure receives sound waves from the sound-emitting portion of the loudspeaker through the opening in the cap; and
the loudspeaker generates the speaker output signal and transmits the speaker output signal to the external audio interface via the audio signal connectors for analysis.

11. The system of claim 9, further comprising:
a current sensing circuit electrically connected to the audio signal connectors and configured to measure a current associated with the speaker output signal as it returns from the loudspeaker to the external audio interface; and
a voltage sensing circuit electrically connected to the audio signal connectors and configured to measure a voltage associated with the speaker output signal as it returns from the loudspeaker to the external audio interface.

12. The system of claim 9, further comprising a processing unit communicatively coupled to the external audio interface, the processing unit configured to:
receive voltage and current data corresponding to the speaker output signal; and
determine an electrical impedance of the loudspeaker based on the voltage and current data, wherein the electrical impedance represents acoustic absorption characteristics of the multi-layer cellular structure.

13. The system of claim 12, wherein the processing unit is further configured to:
compare a determined electrical impedance to a predetermined reference range; and
classify the multi-layer cellular structure as acceptable when the determined electrical impedance is at or within the predetermined reference range and as unacceptable when the determined electrical impedance is outside the predetermined reference range.

14. The system of claim 13, further comprising a condition indicator communicatively coupled to the processing unit, wherein the condition indicator generates an alert when the multi-layer cellular structure is classified as unacceptable.

15. The system of claim 12, wherein the processing unit is configured to determine the electrical impedance of the loudspeaker in real-time as the loudspeaker emits sound waves.

16. The system of claim 9, wherein:
the second cross-sectional dimension of the opening in the cap is selected based on a characteristic dimension of the multi-layer cellular structure; and
the characteristic dimension comprising at least one of:
a perforation in a face sheet of the multi-layer cellular structure;
a perforation density in the face sheet of the multi-layer cellular structure; or
a cell cross-sectional dimension of an internal layer within the multi-layer cellular structure.

17. A method for detecting obstructions in a multi-layer cellular structure, the method comprising:
positioning a testing apparatus at an initial testing location that is acoustically permeable on a testing surface of the multi-layer cellular structure, the testing apparatus comprising a loudspeaker enclosed within a tube and configured to emit sound waves toward the multi-layer cellular structure through an opening;
transmitting an input signal from an external audio interface to the loudspeaker via audio signal connectors;
emitting sound waves from the loudspeaker through the opening of the testing apparatus toward the multi-layer cellular structure;
receiving a speaker output signal from the loudspeaker via the audio signal connectors, the speaker output signal providing voltage and current data associated with an interaction of the emitted sound waves with the multi-layer cellular structure; and
determining an electrical impedance of the loudspeaker based on voltage and current data corresponding to the loudspeaker, wherein the electrical impedance represents acoustic absorption characteristics of the multi-layer cellular structure at the initial testing location.

18. The method of claim 17, further comprising:
comparing a determined electrical impedance of the loudspeaker to a predetermined reference range; and
classifying the multi-layer cellular structure as acceptable when the determined electrical impedance is at or within the predetermined reference range and unacceptable when the determined electrical impedance is outside the predetermined reference range.

19. The method of claim 17, further comprising:
repositioning the testing apparatus at a subsequent testing location on the testing surface of the multi-layer cellular structure, wherein the subsequent testing location is spaced apart from the initial testing location; and
determining a subsequent electrical impedance of the loudspeaker at the subsequent testing location based on voltage and current data corresponding to the loudspeaker at the subsequent testing location, wherein the subsequent electrical impedance represents acoustic absorption characteristics of the multi-layer cellular structure at the subsequent testing location.

20. The method of claim 17, wherein determining the electrical impedance of the loudspeaker is determined in real-time as the loudspeaker emits sound waves at the initial testing location.
